(19) United States
(12) Patent Application Publication
(10) Pub. No.: US 2006/0062910 A1
(43) Pub. Date: Mar. 23, 2006

(54) Low zirconium, hafnium-containing compositions, processes for the preparation thereof and methods of use thereof

(76) Inventor: Scott Houston Meiere, Williamsville, NY (US)

Correspondence Address: PRAXAIR, INC.;LAW DEPARTMENT - M1 557, 39 OLD RIDGEBURY ROAD, DANBURY, CT, 06810-5113, US

(21) Appl. No.: 11/245,104

(22) Filed: Oct. 7, 2005

Related U.S. Application Data
(63) Continuation-in-part of application No. 11/063,638, filed on Feb. 24, 2005.
(60) Provisional application No. 60/548,167, filed on Mar. 1, 2004.

(30) Foreign Application Priority Data
Feb. 23, 2005 (TW) SN 94105447

(51) Int. Cl. B05D 3/02; C23C 16/00; C07F 7/28

(52) U.S. Cl. 427/226; 427/248.1; 556/52

(57) ABSTRACT

This invention relates to hafnium-containing compositions having a zirconium concentration of less than about 500 parts per million, a process for producing the hafnium-containing compositions, organometallic precursor compositions containing a hafnium-containing compound and having a zirconium concentration of less than about 500 parts per million, a process for producing the organometallic precursor compositions, and a method for producing a film or coating from the organometallic precursor compositions. The organometallic precursor compositions are useful in semiconductor applications as chemical vapor deposition (CVD) or atomic layer deposition (ALD) precursors for film depositions.

### RELATED APPLICATIONS

This application claims the benefit of U.S. patent application Ser. No. 11/063,638, filed on Feb. 24, 2005, and U.S. Provisional Application Ser. No. 60/548,167, filed on Mar. 1, 2004, the entire teachings of both are incorporated herein by reference.

### FIELD OF THE INVENTION

This invention relates to low zirconium, hafnium-containing compositions, a process for producing the low zirconium, hafnium-containing compositions, and a method for producing a film or coating from the low zirconium, hafnium-containing compositions.

### BACKGROUND OF THE INVENTION

Chemical vapor deposition methods are employed to form films of material on substrates such as wafers or other surfaces during the manufacture or processing of semiconductors. In chemical vapor deposition, a chemical vapor deposition precursor, also known as a chemical vapor deposition chemical compound, is decomposed thermally, chemically, photochemically or by plasma activation, to form a thin film having a desired composition. For instance, a vapor phase chemical vapor deposition precursor can be contacted with a substrate that is heated to a temperature higher than the decomposition temperature of the precursor, to form a metal or metal oxide film on the substrate. Preferably, chemical vapor deposition precursors are volatile, heat decomposable and capable of producing uniform films under chemical vapor deposition conditions.

The semiconductor industry is currently considering the use of thin films of various metals for a variety of applications. Many organometallic complexes have been evaluated as potential precursors for the formation of these thin films. A need exists in the industry for developing new compounds and for exploring their potential as chemical vapor deposition precursors for film depositions.

Hafnium oxides, silicates, and/or aluminates are candidates for next-generation materials for the electronics industry, replacing SiO₂ with a ‘high-k’ dielectric. The process for depositing these films will likely be chemical vapor deposition or atomic layer deposition. The precursor candidates for this deposition process include hafnium-containing materials such as hafnium amides, hafnium alkoxides, and the like. For such precursor candidates, it is highly probable that hafnium chloride (HfCl₄) will be used in the precursor synthesis.

For hafnium-containing precursors, it is important that the zirconium content in hafnium precursors be minimized or eliminated so as to avoid potential problems such as inconsistent or poor device performance due to zirconium impurities in the films. Hafnium and zirconium are two of the most similar elements on the periodic table. Because they are so similar, the separation of hafnium and zirconium is extremely difficult, and has been studied at length due, in some part, to the nuclear industry applications for the materials. The common method of purification is by distillation/sublimation. There is typically about 1-3% zirconium in industrially processed hafnium chloride. For highly pure material, sometimes referred to as spectroscopic or sublimed grade, the zirconium content is commonly between 0.10 and 0.3% (1000-3000 parts per million). However, continually purifying hafnium chloride to low zirconium levels by sublimation can be a tedious process, and not a very efficient one. Obtaining relatively low zirconium levels (perhaps as low as a few hundred parts per million) can be accomplished by careful sublimation, but will likely not access ultra low (<100 parts per million) levels of zirconium in any type of efficient manner. An alternative method to produce hafnium chloride of higher purity would be beneficial.

In developing methods for forming thin films by chemical vapor deposition methods, a need continues to exist for chemical vapor deposition precursors that preferably have relatively high vapor pressure and can form uniform films. Therefore, a need continues to exist for developing new compounds and for exploring their potential as chemical vapor deposition precursors for film depositions. It would therefore be desirable in the art to provide a chemical vapor deposition precursor having a high vapor pressure and that can form uniform films and does not introduce any contaminants.

### SUMMARY OF THE INVENTION

This invention relates in part to a composition comprising a hafnium-containing compound represented by the formula Hf(R)ₘ wherein R is the same or different and represents a halogen atom, a pseudohalogen group, an acyl group having from 1 to about 12 carbon atoms, an alkoxy group having from 1 to about 12 carbon atoms, an alkoxycarbonyl group having from 1 to about 12 carbon atoms, an alkyl group having from 1 to about 12 carbon atoms, an amino group having from 1 to about 12 carbon atoms, an imino group having from 1 to about 12 carbon atoms, a silyl group having from 0 to about 12 carbon atoms, an allyl-like group having from 1 to about 12 carbon atoms, a beta-diketonato group having from 1 to about 12 carbon atoms, or an amidinato group having from 1 to about 12 carbon atoms, m is a value of from 1 to 4, and wherein said composition has a zirconium concentration of less than about 500 parts per million, preferably less than about 100 parts per million, and more preferably less than about 10 parts per million.

This invention also relates in part to an organometallic precursor composition comprising a hafnium-containing compound represented by the formula Hf(R)ₘ wherein R is the same or different and represents a halogen atom, a pseudohalogen group, an acyl group having from 1 to about 12 carbon atoms, an alkoxy group having from 1 to about 12 carbon atoms, an alkoxycarbonyl group having from 1 to about 12 carbon atoms, an alkyl group having from 1 to about 12 carbon atoms, an amino group having from 1 to about 12 carbon atoms, an imino group having from 1 to about 12 carbon atoms, a silyl group having from 0 to about 12 carbon atoms, an allyl-like group having from 1 to about 12 carbon atoms, a beta-diketonato group having from 1 to about 12 carbon atoms, or an amidinato group having from 1 to about 12 carbon atoms, m is a value of from 1 to 4, and wherein said composition has a zirconium concentration of less than about 500 parts per million, preferably less than about 100 parts per million, and more preferably less than about 10 parts per million.

This invention pertains to chemical vapor deposition and atomic layer deposition precursors for next generation devices, specifically hafnium-containing precursors including hafnium chloride and those precursors that use hafnium chloride as a starting material such as tetrakis(dimethylamino)hafnium (TDMAH), tetrakis(ethylmethylamino)hafnium (TEMAH), tetrakis(diethylamino)hafnium (TDEAH), hafnium amide, hafnium (IV) tert-butoxide, hafnium (IV) acetylacetonate, bis(ethylcyclopentadienyl)dimethylhafnium or t-butylimidobis(dimethylamino)hafnium.

This invention further relates in part to a process for producing a composition comprising a hafnium-containing compound represented by the formula Hf(R)ₘ wherein R is the same or different and represents a halogen atom, a pseudohalogen group, an acyl group having from 1 to about 12 carbon atoms, an alkoxy group having from 1 to about 12 carbon atoms, an alkoxycarbonyl group having from 1 to about 12 carbon atoms, an alkyl group having from 1 to about 12 carbon atoms, an amino group having from 1 to about 12 carbon atoms, an imino group having from 1 to about 12 carbon atoms, a silyl group having from 0 to about 12 carbon atoms, an allyl-like group having from 1 to about 12 carbon atoms, a beta-diketonato group having from 1 to about 12 carbon atoms, or an amidinato group having from 1 to about 12 carbon atoms, m is a value of from 1 to 4, and wherein said composition has a zirconium concentration of less than about 500 parts per million, preferably less than about 100 parts per million, and more preferably less than about 10 parts per million, which process comprises reacting a hydrocarbon or heteroatom-containing compound with a hafnium halide compound represented by the formula Hf(X)₄ wherein X is the same or different and is a halide (e.g., Cl, Br, I or F) and wherein said hafnium halide compound has a zirconium concentration of less than about 500 parts per million, preferably less than about 100 parts per million, and more preferably less than about 10 parts per million, under reaction conditions sufficient to produce said composition.

This invention yet further relates in part to a method for producing a hafnium-containing film, coating or powder having a zirconium concentration of less than about 500 parts per million, preferably less than about 100 parts per million, and more preferably less than about 10 parts per million, which method comprises decomposing an organometallic precursor composition comprising a hafnium-containing compound, thereby producing the film, coating or powder, wherein said hafnium-containing compound is represented by the formula Hf(R)ₘ wherein R is the same or different and represents a halogen atom, a pseudohalogen group, an acyl group having from 1 to about 12 carbon atoms, an alkoxy group having from 1 to about 12 carbon atoms, an alkoxycarbonyl group having from 1 to about 12 carbon atoms, an alkyl group having from 1 to about 12 carbon atoms, an amino group having from 1 to about 12 carbon atoms, an imino group having from 1 to about 12 carbon atoms, a silyl group having from 0 to about 12 carbon atoms, an allyl-like group having from 1 to about 12 carbon atoms, a beta-diketonato group having from 1 to about 12 carbon atoms, or an amidinato group having from 1 to about 12 carbon atoms, m is a value of from 1 to 4, and wherein said organometallic precursor composition has a zirconium concentration of less than about 500 parts per million, preferably less than about 100 parts per million, and more preferably less than about 10 parts per million.

This invention also relates to a mixture comprising (i) a composition comprising a hafnium-containing compound represented by the formula Hf(R)ₘ wherein R is the same or different and represents a halogen atom, a pseudohalogen group, an acyl group having from 1 to about 12 carbon atoms, an alkoxy group having from 1 to about 12 carbon atoms, an alkoxycarbonyl group having from 1 to about 12 carbon atoms, an alkyl group having from 1 to about 12 carbon atoms, an amino group having from 1 to about 12 carbon atoms, an imino group having from 1 to about 12 carbon atoms, a silyl group having from 0 to about 12 carbon atoms, an allyl-like group having from 1 to about 12 carbon atoms, a beta-diketonato group having from 1 to about 12 carbon atoms, or an amidinato group having from 1 to about 12 carbon atoms, m is a value of from 1 to 4, and wherein said composition has a zirconium concentration of less than about 500 parts per million, preferably less than about 100 parts per million, and more preferably less than about 10 parts per million, and (ii) one or more different organometallic compounds (e.g., a ruthenium-containing, tantalum-containing or molybdenum-containing organometallic compound).

This invention relates in particular to depositions involving hafnium-containing precursors. These precursors can provide advantages over the other known precursors, especially when utilized in tandem with other ‘next-generation’ materials (e.g., ruthenium, tantalum and molybdenum). These hafnium-containing materials can be used for a variety of purposes such as dielectrics, barriers, and electrodes, and in many cases show improved properties (thermal stability, desired morphology, less diffusion, lower leakage, less charge trapping, and the like) than the non-hafnium containing films.

The invention has several advantages. For example, the method of the invention is useful in generating hafnium-containing compound precursors that have varied chemical structures and physical properties. Films generated from the hafnium-containing compound precursors can be deposited with a short incubation time, and the films deposited from the hafnium-containing compound precursors exhibit good smoothness.

Since hafnium typically contains a substantial amount of zirconium (about 1000 parts per million for high purity precursor materials), there has been a concern that this contaminant may cause device issues. However, the ultra-high purity (UHP) hafnium-containing precursors (e.g., CVD, ALD) of this invention have heretofore been unavailable for evaluation, therefore this potential problem has loomed as an unknown. This invention provides hafnium-containing precursors with zirconium levels less than 100 parts per million, preferably less than 5 parts per million. The ultra high purity precursors of this invention can provide advantages over standard grade hafnium-containing precursors. The hafnium-based films generated with the UHP hafnium-containing precursors can show far less metal impurities, not only Zr (around 3 order of magnitude less), but also other trace metals. The UHP hafnium-containing material can also show improvements with reliability for logic applications.

### DESCRIPTION OF THE DRAWINGS

FIG. 1 depicts in general an apparatus for making ultra high purity (UHP) hafnium chloride.

### DETAILED DESCRIPTION OF THE INVENTION

As indicated above, this invention relates in part to a composition comprising a hafnium-containing compound represented by the formula Hf(R)ₘ wherein R is the same or different and represents a halogen atom, a pseudohalogen group, an acyl group having from 1 to about 12 carbon atoms, an alkoxy group having from 1 to about 12 carbon atoms, an alkoxycarbonyl group having from 1 to about 12 carbon atoms, an alkyl group having from 1 to about 12 carbon atoms, an amino group having from 1 to about 12 carbon atoms, an imino group having from 1 to about 12 carbon atoms, a silyl group having from 0 to about 12 carbon atoms, an allyl-like group having from 1 to about 12 carbon atoms, a beta-diketonato group having from 1 to about 12 carbon atoms, or an amidinato group having from 1 to about 12 carbon atoms, m is a value of from 1 to 4, and wherein said composition has a zirconium concentration of less than about 500 parts per million, preferably less than about 100 parts per million, and more preferably less than about 10 parts per million.

As also indicated above, this invention relates in part to an organometallic precursor composition comprising a hafnium-containing compound represented by the formula Hf(R)ₘ wherein R is the same or different and represents a halogen atom, a pseudohalogen group, an acyl group having from 1 to about 12 carbon atoms, an alkoxy group having from 1 to about 12 carbon atoms, an alkoxycarbonyl group having from 1 to about 12 carbon atoms, an alkyl group having from 1 to about 12 carbon atoms, an amino group having from 1 to about 12 carbon atoms, an imino group having from 1 to about 12 carbon atoms, a silyl group having from 0 to about 12 carbon atoms, an allyl-like group having from 1 to about 12 carbon atoms, a beta-diketonato group having from 1 to about 12 carbon atoms, or an amidinato group having from 1 to about 12 carbon atoms, m is a value of from 1 to 4, and wherein said composition has a zirconium concentration of less than about 500 parts per million, preferably less than about 100 parts per million, and more preferably less than about 10 parts per million.

Illustrative halogen atoms and pseudohalogen groups that may be used in R include, for example, fluorine, chlorine, bromine, iodine, nitrate and cyanate. Preferred halogen atoms and pseudohalogen groups include chlorine and nitrate.

Illustrative acyl groups that may be used in R include, for example, formyl, acetyl, propionyl, butyryl, isobutyryl, valeryl, 1-methylpropylcarbonyl, isovaleryl, pentylcarbonyl, 1-methylbutylcarbonyl, 2-methylbutylcarbonyl, 3-methylbutylcarbonyl, 1-ethylpropylcarbonyl, 2-ethylpropylcarbonyl, and the like. Preferred acyl groups include formyl, acetyl and propionyl.

Illustrative alkoxy groups that may be used in R include, for example, methoxy, ethoxy, n-propoxy, isopropoxy, n-butoxy, isobutoxy, sec-butoxy, tert-butoxy, pentyloxy, 1-methylbutyloxy, 2-methylbutyloxy, 3-methylbutyloxy, 1,2-dimethylpropyloxy, hexyloxy, 1-methylpentyloxy, 1-ethylpropyloxy, 2-methylpentyloxy, 3-methylpentyloxy, 4-methylpentyloxy, 1,2-dimethylbutyloxy, 1,3-dimethylbutyloxy, 2,3-dimethylbutyloxy, 1,1-dimethylbutyloxy, 2,2-dimethylbutyloxy, 3,3-dimethylbutyloxy, 1-methoxy-2-methyl-2-propoxide, and the like. Preferred alkoxy groups include methoxy, ethoxy and propoxy.

Illustrative alkoxycarbonyl groups that may be used in R include, for example, methoxycarbonyl, ethoxycarbonyl, propoxycarbonyl, isopropoxycarbonyl, cyclopropoxycarbonyl, butoxycarbonyl, isobutoxycarbonyl, sec-butoxycarbonyl, tert-butoxycarbonyl, and the like. Preferred alkoxycarbonyl groups include methoxycarbonyl, ethoxycarbonyl, propoxycarbonyl, isopropoxycarbonyl and cyclopropoxycarbonyl.

Illustrative alkyl groups that may be used in R include, for example, methyl, ethyl, n-propyl, isopropyl, n-butyl, isobutyl, sec-butyl, tert-butyl, pentyl, isopentyl, neopentyl, tert-pentyl, 1-methylbutyl, 2-methylbutyl, 1,2-dimethylpropyl, hexyl, isohexyl, 1-methylpentyl, 2-methylpentyl, 3-methylpentyl, 1,1-dimethylbutyl, 2,2-dimethylbutyl, 1,3-dimethylbutyl, 2,3-dimethylbutyl, 3,3-dimethylbutyl, 1-ethylbutyl, 2-ethylbutyl, 1,1,2-trimethylpropyl, 1,2,2-trimethylpropyl, 1-ethyl-1-methylpropyl, 1-ethyl-2-methylpropyl, cyclopropyl, cyclobutyl, cyclopentyl, cyclohexyl, cyclopropylmethyl, cyclopropylethyl, cyclobutylmethyl, benzyl, and the like. Preferred alkyl groups include methyl, ethyl, n-propyl, isopropyl, benzyl, and cyclohexyl.

Illustrative amino groups that may be used in R include, for example, methylamino, dimethylamino, ethylamino, diethylamino, propylamino, dipropylamino, isopropylamino, diisopropylamino, isopropylmethylamino, isopropylethylamino, butylamino, dibutylamino, tert-butylamino, di(tert-butyl)amino, ethylmethylamino, butylmethylamino, tert-butylmethylamino, cyclohexylamino, dicyclohexylamino, trimethylsilylamino, bis(trimethylsilyl)amino, trimethylsilylmethylamino, and the like. Preferred amino groups include dimethylamino, ethylmethylamino, and diethylamino.

Illustrative imine groups that may be used for R include, for example, tert-butylimino, isopropylimino, ethylimino, methylimino, and the like. Preferred imino groups include tert-butylimino and isopropylimino.

Illustrative silyl groups that may be used in R include, for example, silyl, trimethylsilyl, triethylsilyl, tris(trimethylsilyl)methyl, trisilylmethyl, methylsilyl and the like. Preferred silyl groups include silyl, trimethylsilyl and triethylsilyl.

Illustrative allyl-like groups that may be used in R include, for example, allyl, 2-methylallyl, 2-tert-butylallyl, cyclopentadienyl, methylcyclopentadienyl, ethylcyclopentadienyl, pentadienyl, 2,4-dimethylpentadienyl, cyclohexadienyl, hexadienyl, cycloheptadienyl, heptadienyl, and the like. Preferred allyl-like groups include ethylcyclopentadienyl and 2-tert-butylallyl.

Illustrative beta-diketonate groups that may be used for R include, for example, acetylacetonato, hexafluoroacetylacetonato, 2,2,6,6-tetramethyl-3,5-heptanedionato, 6,6,7,7,8,8,8-heptafluoro-2,2-dimethyl-3,5-octanedionato, and the like. Preferred beta-diketonate groups include acetylacetonato and 2,2,6,6-tetramethyl-3,5-heptanedionato.

Illustrative amidinate groups that may be used for R include, for example, diisopropylacetamidinato, di-tert-butylacetamidinato, and the like. Preferred amidinate groups include di-tert-butylacetamidinato.

Illustrative hafnium-containing compounds of this invention include, for example, tetrakis(dimethylamino)hafnium (TDMAH), tetrakis(ethylmethylamino)hafnium (TEMAH), tetrakis(diethylamino)hafnium (TDEAH), hafnium amide, hafnium (IV) tert-butoxide, hafnium (IV) acetylacetonate, bis(ethylcyclopentadienyl)dimethylhafnium or t-butylimidobis(dimethylamino)hafnium.

As further indicated above, this invention relates to a process for producing a composition (e.g., organometallic precursor composition) comprising a hafnium-containing compound represented by the formula Hf(R)ₘ wherein R is the same or different and represents a halogen atom, a pseudohalogen group, an acyl group having from 1 to about 12 carbon atoms, an alkoxy group having from 1 to about 12 carbon atoms, an alkoxycarbonyl group having from 1 to about 12 carbon atoms, an alkyl group having from 1 to about 12 carbon atoms, an amino group having from 1 to about 12 carbon atoms, an imino group having from 1 to about 12 carbon atoms, a silyl group having from 0 to about 12 carbon atoms, an allyl-like group having from 1 to about 12 carbon atoms, a beta-diketonato group having from 1 to about 12 carbon atoms, or an amidinato group having from 1 to about 12 carbon atoms, m is a value of from 1 to 4, and wherein said composition has a zirconium concentration of less than about 500 parts per million, preferably less than about 100 parts per million, and more preferably less than about 10 parts per million, which process comprises reacting a hydrocarbon or heteroatom-containing compound with a hafnium halide compound represented by the formula Hf(X)₄ wherein X is the same or different and is a halide (e.g., Cl, Br, I or F) and wherein said hafnium halide compound has a zirconium concentration of less than about 500 parts per million, preferably less than about 100 parts per million, and more preferably less than about 10 parts per million, under reaction conditions sufficient to produce said composition.

In an embodiment, this invention also involves a process for producing an organometallic compound comprising (i) reacting a hydrocarbon or heteroatom-containing material with a base material in the presence of a solvent and under reaction conditions sufficient to produce a first reaction mixture comprising a hydrocarbon or heteroatom-containing compound, (ii) adding a metal source compound to said first reaction mixture, (iii) reacting said hydrocarbon or heteroatom-containing compound with said metal source compound under reaction conditions sufficient to produce a second reaction mixture comprising said organometallic compound, and (iv) separating said organometallic compound from said second reaction mixture. The method is particularly well-suited for large scale production since it can be conducted using the same equipment, some of the same reagents and process parameters that can easily be adapted to manufacture a wide range of products. The method provides for the synthesis of organometallic compounds using a unique process where all manipulations are carried out in a single vessel, and which route to the organometallic compounds does not require the isolation of an intermediate complex. This method is more fully described in U.S. patent application Ser. No. 10/678,074, filed Oct. 6, 2003, which is incorporated herein by reference.

With respect to the preparation of the hafnium halide compound, the one compound of hafnium that currently can be obtained commercially with very low zirconium levels is hafnium oxide. By various separation methods (e.g., extraction, ion flotation, froth floatation, solvent sublation), not suitable for the more reactive hafnium chloride, the inert hafnium oxide (HfO₂) may be purified to levels of less than 50 parts per million zirconium. Hafnium oxide, however, is not a suitable precursor due to its lack of appreciable volatility/reactivity.

Starting with high purity hafnium oxide one can synthesize hafnium chloride with low zirconium levels utilizing a single reaction. The processes of this invention employ high purity hafnium chloride. Also, the processes do not require fractional or multiple sublimation steps.

The processing of hafnium and zirconium most often begins with the ore zircon, MSiO₄ (where M=zirconium with some hafnium). The ore is chlorinated at high temperature (˜900° C.) in the presence of chlorine and carbon to produce zirconium/hafnium tetrachloride, SiCl₄, and CO₂, the latter two being separated easily due to higher volatility (U.S. Pat. No. 5,102,637). With the silicon removed, the hafnium and zirconium halides are converted to oxides or oxychlorides and separated in a number of ways such as disclosed in U.S. Pat. No. 2,944,878 depending on the purity desired. Finally, to isolate the now separated metals, the oxides are commonly re-chlorinated with chlorine over carbon to generate the pure tetrachloride.

There are a number of ways to chlorinate metal oxides that may be used in the processes of this invention. Illustrative processes for chlorinating metal oxides are as follows:
MSiO₄+4Cl₂+2C→MCl₄+SiCl₄+2CO₂
MO₂+2Cl₂+C→MCl₄+CO₂
MO₂+CCl₄→MCl₄+CO₂
(M=a transition metal such as hafnium or zirconium)

The chlorination of hafnium and zirconium oxide is known in the literature on the industrial scale, although not utilizing low zirconium hafnium oxide. Illustrative chlorination processes are described, for example, in U.S. Pat. No. 3,293,005 and Sheridan, C. W. et al. ‘Preparation of Charge Materials for ORNL Electromagnetic Isotope Separators’ Oak Ridge National Laboratory 1962.

The metal oxide, e.g., hafnium oxide, starting material may be selected from a wide variety of compounds known in the art. Almost all metals have a commonly occurring oxide, therefore the range of metals that could feasibly be used covers almost the entire periodic table. The invention herein most prefers the Group 4 metals, then prefers the transition elements including the lanthanides. When employing hafnium oxide, it is important that the zirconium concentration in the hafnium oxide be less than about 500 parts per million, preferably less than about 100 parts per million, and more preferably least than about 10 parts per million. In another embodiment, the hafnium oxide may preferably have a zirconium concentration of less than about 5 parts per million.

The concentration of the hafnium oxide starting material can vary over a wide range, and need only be that minimum amount necessary to react with a halogen or halogen-containing compound starting material. In general, depending on the size of the reaction mixture, hafnium oxide starting material concentrations in the range of from about 1 millimole or less to about 1,000,000 millimoles or greater, should be sufficient for most processes.

The halogen and halogen-containing compound may be selected from a wide variety of compounds known in the art, e.g., chlorine, bromine, iodine, fluorine, chlorides, bromides, iodides, fluorides, and the like. Illustrative halides exist for most metals. Therefore, with a proper choice of halogen and halogen-containing compound source (including chlorine gas, organic chlorine sources (e.g., carbon tetrachloride, phosgene, and the like), and inorganic chlorine sources (e.g., PbCl₂), and suitable temperature and pressure, the hafnium halide compounds can feasibly be formed. The invention herein most prefers chlorine or carbon tetrachloride, than other organic or inorganic sources.

The concentration of the halogen or halogen-containing compound starting material can vary over a wide range, and need only be that minimum amount necessary to react with the hafnium oxide starting material. In general, depending on the size of the reaction mixture, halogen and halogen-containing compound starting material concentrations in the range of from about 1 millimole or less to about 1,000,000 millimoles or greater, should be sufficient for most processes.

The addition of supporting agents may also be employed in the process of this invention for producing a composition comprising a hafnium halide compound. Such supporting agents can be useful, for example, for more facile removal of oxygen. In these type of processes, supporting agents such as carbon can be added to allow for the formation of carbon dioxide. Purge/carrier gas in addition any reactive gases utilized such as chlorine, can be utilized and chosen from many inert gases such as nitrogen, helium, argon, and the like.

The hafnium halide compounds prepared from the reaction of the hafnium oxide starting material and the halogen or halogen-containing compound starting material may be selected from a wide variety of compounds known in the art. Illustrative hafnium halide compounds include, for example, HfCl₄, HfF₄, HfBr₄, or HfI₄ and the like.

Reaction conditions for the reaction of the hafnium oxide starting material with the halogen and halogen-containing compound starting material, such as temperature, pressure and contact time, may also vary greatly and any suitable combination of such conditions may be employed herein. The reaction temperature may range from about 25° C. or less to about 1000° C. or greater, more preferably at about 400-600° C., and feasibly at almost any attainable temperature. Normally the reaction is carried out under a pressure of about 0.1 torr or less to about 1500 torr or greater, more preferably at about 700-900 torr, and feasibly at any attainable pressure. The contact time for the reaction may vary from a matter of seconds or minutes to a few hours or greater. The reactants can be added to the reaction mixture or combined in any order. The mixing time employed can range from about 0.01 to about 400 hours, preferably from about 0.1 to 75 hours, and more preferably from about 0.5 to 8 hours, for all steps.

In the case described herein, the final hafnium halide product is isolated by a sublimation technique. Other techniques that are conceivable include chromatography, crystallization, extraction, distillation, ion flotation, froth floatation, solvent sublation, and the like.

Illustrative reactors suitable for the process of this invention include, for example, flow through, fluidized bed, packed column and pressurized vessel. The material of construction of the reactor can be a variety of compositions including quartz (favored herein), glass, stainless steel, other metal and metal alloys, plastics and other polymeric materials. Choice of material is highly dependent on temperatures, pressures, chlorinating agents, and the like.

The hydrocarbon or heteroatom-containing starting material may be selected from a wide variety of compounds known in the art. Illustrative hydrocarbon or heteroatom-containing compounds include, for example, amines, alcohols, diketones, cyclopentadienes, imines, hydrocarbons, halogens and the like. Preferred hydrocarbon or heteroatom-containing starting materials include amines having the formula HNR′R″ wherein R′ and R″ are independently methyl, ethyl, propyl, butyl, isopropyl, tert-butyl and the like or R′ and R″ can be connected together to form a substituted or unsubstituted cyclic amine, e.g., pyrrolidine, piperidine and the like. Other amines that may be useful in the method of this invention include those having the formulae HNR′R″, H₂NR′ and NH₃ wherein R′ and R″ are independently a saturated or unsaturated, branched or unbranched, hydrocarbon chain or a ring consisting of less than about 20 carbon atoms, alkyl halide, silane, ether, thioether, ester, thioester, amide, amine, nitrile, ketone or mixtures of the above groups.

The concentration of the hydrocarbon or heteroatom-containing starting material can vary over a wide range, and need only be that minimum amount necessary to react with the base starting material. In general, depending on the size of the first reaction mixture, hydrocarbon or heteroatom-containing starting material concentrations in the range of from about 1 millimole or less to about 1,000,000 millimoles or greater, should be sufficient for most processes.

The base starting material may be selected from a wide variety of compounds known in the art. Illustrative bases include any base with a pKa greater than about 10, preferably greater than about 20, and more preferably greater than about 25. The base material is preferably n-BuLi, t-BuLi, MeLi, NaH, CaH₂, lithium amides and the like.

The concentration of the base starting material can vary over a wide range, and need only be that minimum amount necessary to react with the hydrocarbon or heteroatom-containing starting material. In general, depending on the size of the first reaction mixture, base starting material concentrations in the range of from about 1 millimole or less to about 1,000,000 millimoles or greater, should be sufficient for most processes.

In one embodiment, the hydrocarbon or heteroatom-containing compound may be generated in situ, for example, lithiated amides, alkoxides, diketonates, cyclopentadienides, imides and the like. Generating the hydrocarbon or heteroatom-containing compound in situ in the reaction vessel immediately prior to reaction with the metal source compound is beneficial from a purity standpoint by eliminating the need to isolate and handle any reactive solids. It is also less expensive.

With the in situ generated hydrocarbon or heteroatom-containing compound in place, addition of the high purity hafnium halide compound, e.g., hafnium chloride, can be performed through solid addition, or in some cases more conveniently as a solvent (e.g., hexanes) slurry. Although certain metal source compounds are moisture sensitive and are used under an inert atmosphere such as nitrogen, it is generally to a much lower degree than the hydrocarbon or heteroatom-containing compounds, for example, lithiated amides, alkoxides, diketonates, cyclopentadienides, imides and the like. Furthermore, many metal source compounds such as HfCl₄ are denser and easier to transfer.

The hydrocarbon or heteroatom-containing compounds prepared from the reaction of the hydrocarbon or heteroatom-containing starting material and the base starting material may be selected from a wide variety of compounds known in the art. Illustrative hydrocarbon or heteroatom-containing compounds include, for example, lithiated amides, alkoxides, diketonates, cyclopentadienides, imides and the like.

The concentration of the hydrocarbon or heteroatom-containing compounds can vary over a wide range, and need only be that minimum amount necessary to react with the metal source, e.g., hafnium halide, compounds to give the organometallic compounds of this invention. In general, depending on the size of the second reaction mixture, hydrocarbon or heteroatom-containing compound concentrations in the range of from about 1 millimole or less to about 1,000,000 millimoles or greater, should be sufficient for most processes.

The solvent employed in the method of this invention may be any saturated and unsaturated hydrocarbons, aromatic hydrocarbons, aromatic heterocycles, alkyl halides, silylated hydrocarbons, ethers, polyethers, thioethers, esters, thioesters, lactones, amides, amines, polyamines, nitriles, silicone oils, other aprotic solvents, or mixtures of one or more of the above; more preferably, diethylether, pentanes, or dimethoxyethanes; and most preferably hexanes or THF. Any suitable solvent which does not unduly adversely interfere with the intended reaction can be employed. Mixtures of one or more different solvents may be employed if desired. The amount of solvent employed need only be that amount sufficient to solubilize the reaction components in the reaction mixture. In general, the amount of solvent may range from about 5 percent by weight up to about 99 percent by weight or more based on the total weight of the reaction mixture starting materials.

Reaction conditions for the reaction of the base starting material with the hydrocarbon or heteroatom-containing material, such as temperature, pressure and contact time, may also vary greatly and any suitable combination of such conditions may be employed herein. The reaction temperature may be the reflux temperature of any of the aforementioned solvents, and more preferably between about −80° C. to about 150° C., and most preferably between about 20° C. to about 80° C. Normally the reaction is carried out under ambient pressure and the contact time may vary from a matter of seconds or minutes to a few hours or greater. The reactants can be added to the reaction mixture or combined in any order. The stir time employed can range from about 0.1 to about 400 hours, preferably from about 1 to 75 hours, and more preferably from about 4 to 16 hours, for all steps.

The high purity metal source, e.g., hafnium halide, compound may be selected from a wide variety of metal-containing compounds known in the art, preferably the high purity hafnium-containing compound above represented by the formula Hf(X)₄. Illustrative metals include hafnium, zirconium, titanium, tantalum, molybdenum and other transition metals. The high purity metal source compound is preferably a transition metal halide compound, more preferably MXₙ (where M is a transition metal, X is halide and n is a value of 3, 4 or 5) including HfCl₄, HfF₄, HfBr₄, HfI₄, Hf(OTf)₄ and the like, and most preferably HfCl₄. Other metal source compounds may include hafnium metal, HfOCl₂ and the like.

The concentration of the high purity metal source, e.g., hafnium halide, compound can vary over a wide range, and need only be that minimum amount necessary to provide the given metal concentration desired to be employed and which will furnish the basis for at least the amount of metal necessary for the organometallic compounds of this invention. In general, depending on the size of the first reaction mixture, metal source compound concentrations in the range of from about 1 millimole or less to about 1,000,000 millimoles or greater, should be sufficient for most processes.

Reaction conditions for the reaction of the hydrocarbon or heteroatom-containing compound with the high purity metal source, e.g., hafnium halide, compound, such as temperature, pressure and contact time, may also vary greatly and any suitable combination of such conditions may be employed herein. The reaction temperature may be the reflux temperature of any of the aforementioned solvents, and more preferably between about −80° C. to about 150° C., and most preferably between about 20° C. to about 80° C. Normally the reaction is carried out under ambient pressure and the contact time may vary from a matter of seconds or minutes to a few hours or greater. The reactants can be added to the reaction mixture or combined in any order. The stir time employed can range from about 0.1 to about 400 hours, preferably from about 1 to 75 hours, and more preferably from about 4 to 16 hours, for all steps. In the embodiment of this invention which is carried out in a single pot, the hydrocarbon or heteroatom-containing compound is not separated from the first reaction mixture prior to reacting with the high purity metal source compound. In a preferred embodiment, the high purity metal source compound is added to the first reaction mixture at ambient temperature or at a temperature greater than ambient temperature.

The organometallic compounds prepared from the reaction of the hydrocarbon or heteroatom-containing compound and the high purity metal source, e.g., hafnium halide, compound may be selected from a wide variety of compounds known in the art. For purposes of this invention, organometallic compounds include compounds having a metal-carbon atom bond as well as compounds having a metal-heteroatom bond. Illustrative organometallic compounds include, for example, transition metal-containing amides (e.g., hafnium amides such as tetrakis(dimethylamino)hafnium), alkoxides (e.g., hafnium (IV) tert-butoxide), diketonates (e.g., hafnium (IV) acetylacetonate), cyclopentadienides (e.g., bis(cyclopentadienyl)hafnium dichloride), imides (e.g., t-butylimidobis(dimethylamino)hafnium) and the like.

For organometallic compounds prepared by the method of this invention, purification can occur through recrystallization, more preferably through extraction of reaction residue (e.g., hexane) and chromatography, and most preferably through sublimation and distillation.

Alternative methods included within the scope of this invention include, for example, the utilization of HCl salts of the desired amine, instead of the amine itself, as the amide source, as well as the elimination of the lithiation step by utilizing excess amine to react with the HfCl₄ and to tie up the resulting HCl generated as a protonated amine chloride.

Furthermore, this process is not limited to hafnium-containing systems. It can also be extended to other metals as well as other anionic ligands. Examples of other metals include, but are not limited to, zirconium, titanium, tantalum, and molybdenum. Other ligands include, but are not limited to, alkoxides, betadiketonates, cyclopentadienides, imides, nitrates, anionic hydrocarbons, halides, carbonates and the like.

Those skilled in the art will recognize that numerous changes may be made to the method described in detail herein, without departing in scope or spirit from the present invention as more particularly defined in the claims below.

Examples of techniques that can be employed to characterize the organometallic compounds formed by the synthetic methods described above include, but are not limited to, analytical gas chromatography, nuclear magnetic resonance, thermogravimetric analysis, inductively coupled plasma mass spectrometry, differential scanning calorimetry, vapor pressure and viscosity measurements.

Relative vapor pressures, or relative volatility, of organometallic compound precursors described above can be measured by thermogravimetric analysis techniques known in the art. Equilibrium vapor pressures also can be measured, for example by evacuating all gases from a sealed vessel, after which vapors of the compounds are introduced to the vessel and the pressure is measured as known in the art.

Many organometallic compound precursors described herein are liquid at room temperature and are well suited for preparing in-situ powders and coatings. For instance, a liquid organometallic compound precursor can be applied to a substrate and then heated to a temperature sufficient to decompose the precursor, thereby forming a metal or metal oxide coating on the substrate. Applying a liquid precursor to the substrate can be by painting, spraying, dipping or by other techniques known in the art. Heating can be conducted in an oven, with a heat gun, by electrically heating the substrate, or by other means, as known in the art. A layered coating can be obtained by applying an organometallic compound precursor, and heating and decomposing it, thereby forming a first layer, followed by at least one other coating with the same or different precursors, and heating.

Liquid organometallic compound precursors such as described above also can be atomized and sprayed onto a substrate. Atomization and spraying means, such as nozzles, nebulizers and others, that can be employed are known in the art.

In preferred embodiments of the invention, an organometallic compound, such as described above, is employed in gas phase deposition techniques for forming powders, films or coatings. The compound can be employed as a single source precursor or can be used together with one or more other precursors, for instance, with vapor generated by heating at least one other organometallic compound or metal complex. More than one organometallic compound precursor, such as described above, also can be employed in a given process.

As idicated above, this invention relates in part to a mixture comprising (i) a composition comprising a hafnium-containing compound represented by the formula Hf(R)m wherein R is the same or different and represents a halogen atom, a pseudohalogen group, an acyl group having from 1 to about 12 carbon atoms, an alkoxy group having from 1 to about 12 carbon atoms, an alkoxycarbonyl group having from 1 to about 12 carbon atoms, an alkyl group having from 1 to about 12 carbon atoms, an amino group having from 1 to about 12 carbon atoms, an imino group having from 1 to about 12 carbon atoms, a silyl group having from 0 to about 12 carbon atoms, an allyl-like group having from 1 to about 12 carbon atoms, a beta-diketonato group having from 1 to about 12 carbon atoms, or an amidinato group having from 1 to about 12 carbon atoms, m is a value of from 1 to 4, and wherein said composition has a zirconium concentration of less than about 500 parts per million, preferably less than about 100 parts per million, and more preferably less than about 10 parts per million, and (ii) one or more different organometallic compounds (e.g., a ruthenium-containing, tantalum-containing or molybdenum-containing organometallic compound).

Deposition can be conducted in the presence of other gas phase components. In an embodiment of the invention, film deposition is conducted in the presence of at least one non-reactive carrier gas. Examples of non-reactive gases include inert gases, e.g., nitrogen, argon, helium, as well as other gases that do not react with the organometallic compound precursor under process conditions. In other embodiments, film deposition is conducted in the presence of at least one reactive gas. Some of the reactive gases that can be employed include but are not limited to hydrazine, oxygen, hydrogen, air, oxygen-enriched air, ozone (O₃), nitrous oxide (N₂O), water vapor, organic vapors and others. As known in the art, the presence of an oxidizing gas, such as, for example, air, oxygen, oxygen-enriched air, O₃, N₂O or a vapor of an oxidizing organic compound, favors the formation of a metal oxide film.

As indicated above, this invention also relates in part to a method for producing a film, coating or powder. The method includes the step of decomposing at least one organometallic compound precursor, thereby producing the film, coating or powder, as further described below.

Deposition processes described herein can be conducted to form a film, powder or coating that includes a single metal or a film, powder or coating that includes a single metal oxide. Mixed films, powders or coatings also can be deposited, for instance mixed metal oxide films. A mixed metal oxide film can be formed, for example, by employing several organometallic precursors, at least one of which being selected from the organometallic compounds described above.

Gas phase film deposition can be conducted to form film layers of a desired thickness, for example, in the range of from about 1 nm to over 1 mm. The precursors described herein are particularly useful for producing thin films, e.g., films having a thickness in the range of from about 10 nm to about 100 nm. Films of hafnium, hafnium oxides, hafnium silicates and hafnium aluminates, for instance, can be considered for fabricating metal electrodes, in particular as n-channel metal electrodes in logic, as capacitor electrodes for DRAM applications, and as dielectric materials.

The method also is suited for preparing layered films, wherein at least two of the layers differ in phase or composition. Examples of layered film include metal-insulator-semiconductor, and metal-insulator-metal.

In an embodiment, the invention is directed to a method that includes the step of decomposing vapor of an organometallic compound precursor described above, thermally, chemically, photochemically or by plasma activation, thereby forming a film on a substrate. For instance, vapor generated by the compound is contacted with a substrate having a temperature sufficient to cause the organometallic compound to decompose and form a film on the substrate.

The organometallic compound precursors can be employed in chemical vapor deposition or, more specifically, in metalorganic chemical vapor deposition methods known in the art. For instance, the organometallic compound precursors described above can be used in atmospheric, as well as in low pressure, chemical vapor deposition processes. The compounds can be employed in hot wall chemical vapor deposition, a method in which the entire reaction chamber is heated, as well as in cold or warm wall type chemical vapor deposition, a technique in which only the substrate is being heated.

The organometallic compound precursors described above also can be used in plasma or photo-assisted chemical vapor deposition processes, in which the energy from a plasma or electromagnetic energy, respectively, is used to activate the chemical vapor deposition precursor. The compounds also can be employed in ion-beam, electron-beam assisted chemical vapor deposition processes in which, respectively, an ion beam or electron beam is directed to the substrate to supply energy for decomposing a chemical vapor deposition precursor. Laser-assisted chemical vapor deposition processes, in which laser light is directed to the substrate to affect photolytic reactions of the chemical vapor deposition precursor, also can be used.

The method of the invention can be conducted in various chemical vapor deposition reactors, such as, for instance, hot or cold-wall reactors, plasma-assisted, beam-assisted or laser-assisted reactors, as known in the art.

Examples of substrates that can be coated employing the method of the invention include solid substrates such as metal substrates, e.g., Al, Ni, Ti, Co, Pt, Ta; metal silicides, e.g., TiSi₂, CoSi₂, NiSi₂; semiconductor materials, e.g., Si, SiGe, GaAs, InP, diamond, GaN, SiC; insulators, e.g., SiO₂, Si₃N₄, HfO₂, Ta₂O₅, Al₂O₃, barium strontium titanate (BST); barrier materials, e.g., TiN, TaN; or on substrates that include combinations of materials. In addition, films or coatings can be formed on glass, ceramics, plastics, thermoset polymeric materials, and on other coatings or film layers. In preferred embodiments, film deposition is on a substrate used in the manufacture or processing of electronic components. In other embodiments, a substrate is employed to support a low resistivity conductor deposit that is stable in the presence of an oxidizer at high temperature or an optically transmitting film.

The method of the invention can be conducted to deposit a film on a substrate that has a smooth, flat surface. In an embodiment, the method is conducted to deposit a film on a substrate used in wafer manufacturing or processing. For instance, the method can be conducted to deposit a film on patterned substrates that include features such as trenches, holes or vias. Furthermore, the method of the invention also can be integrated with other steps in wafer manufacturing or processing, e.g., masking, etching and others.

Chemical vapor deposition films can be deposited to a desired thickness. For example, films formed can be less than 1 micron thick, preferably less than 500 nanometer and more preferably less than 200 nanometers thick. Films that are less than 50 nanometer thick, for instance, films that have a thickness between about 1 and about 20 nanometers, also can be produced.

Organometallic compound precursors described above also can be employed in the method of the invention to form films by atomic layer deposition (ALD) or atomic layer nucleation (ALN) techniques, during which a substrate is exposed to alternate pulses of precursor, oxidizer and inert gas streams. Sequential layer deposition techniques are described, for example, in U.S. Pat. No. 6,287,965 and in U.S. Pat. No. 6,342,277. The disclosures of both patents are incorporated herein by reference in their entirety.

For example, in one ALD cycle, a substrate is exposed, in step-wise manner, to: a) an inert gas; b) inert gas carrying precursor vapor; c) inert gas; and d) oxidizer, alone or together with inert gas. In general, each step can be as short as the equipment will permit (e.g. milliseconds) and as long as the process requires (e.g. several seconds or minutes). The duration of one cycle can be as short as milliseconds and as long as minutes. The cycle is repeated over a period that can range from a few minutes to hours. Film produced can be a few nanometers thin or thicker, e.g., 1 millimeter (mm).

The method of the invention also can be conducted using supercritical fluids. Examples of film deposition methods that use supercritical fluid that are currently known in the art include chemical fluid deposition; supercritical fluid transport-chemical deposition; supercritical fluid chemical deposition; and supercritical immersion deposition.

Chemical fluid deposition processes, for example, are well suited for producing high purity films and for covering complex surfaces and filling of high-aspect-ratio features. Chemical fluid deposition is described, for instance, in U.S. Pat. No. 5,789,027. The use of supercritical fluids to form films also is described in U.S. Pat. No. 6,541,278 B2. The disclosures of these two patents are incorporated herein by reference in their entirety.

In an embodiment of the invention, a heated patterned substrate is exposed to one or more organometallic compound precursors, in the presence of a solvent, such as a near critical or supercritical fluid, e.g., near critical or supercritical CO₂. In the case of CO₂, the solvent fluid is provided at a pressure above about 1000 psig and a temperature of at least about 30° C.

The precursor is decomposed to form a metal film on the substrate. The reaction also generates organic material from the precursor. The organic material is solubilized by the solvent fluid and easily removed away from the substrate. Metal oxide films also can be formed, for example by using an oxidizing gas.

In an example, the deposition process is conducted in a reaction chamber that houses one or more substrates. The substrates are heated to the desired temperature by heating the entire chamber, for instance, by means of a furnace. Vapor of the organometallic compound can be produced, for example, by applying a vacuum to the chamber. For low boiling compounds, the chamber can be hot enough to cause vaporization of the compound. As the vapor contacts the heated substrate surface, it decomposes and forms a metal or metal oxide film. As described above an organometallic compound precursor can be used alone or in combination with one or more components, such as, for example, other organometallic precursors, inert carrier gases or reactive gases.

In a system that can be used in producing films by the method of the invention, raw materials can be directed to a gas-blending manifold to produce process gas that is supplied to a deposition reactor, where film growth is conducted. Raw materials include, but are not limited to, carrier gases, reactive gases, purge gases, precursor, etch/clean gases, and others. Precise control of the process gas composition is accomplished using mass-flow controllers, valves, pressure transducers, and other means, as known in the art. An exhaust manifold can convey gas exiting the deposition reactor, as well as a bypass stream, to a vacuum pump. An abatement system, downstream of the vacuum pump, can be used to remove any hazardous materials from the exhaust gas. The deposition system can be equipped with in-situ analysis system, including a residual gas analyzer, which permits measurement of the process gas composition. A control and data acquisition system can monitor the various process parameters (e.g., temperature, pressure, flow rate, etc.).

The organometallic compound precursors described above can be employed to produce films that include a single metal or a film that includes a single metal oxide. Mixed films also can be deposited, for instance mixed metal oxide films. Such films are produced, for example, by employing several organometallic precursors. Metal films also can be formed, for example, by using no carrier gas, vapor or other sources of oxygen.

Films formed by the methods described herein can be characterized by techniques known in the art, for instance, by X-ray diffraction, Auger spectroscopy, X-ray photoelectron emission spectroscopy, atomic force microscopy, scanning electron microscopy, and other techniques known in the art. Resistivity and thermal stability of the films also can be measured, by methods known in the art.

In addition to their use in semiconductor applications as chemical vapor or atomic layer deposition precursors for film depositions, the organometallic compounds of this invention may also be useful, for example, as catalysts, fuel additives and in organic syntheses.

Various modifications and variations of this invention will be obvious to a worker skilled in the art and it is to be understood that such modifications and variations are to be included within the purview of this application and the spirit and scope of the claims.

### EXAMPLE 1

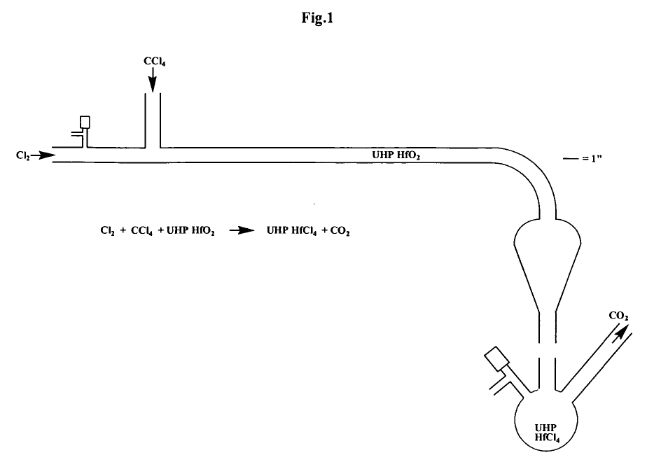

In a walk-in fume hood (equipped with MDA Scientific monitors for measuring sub-parts per million levels of Cl₂ and COCl₂) was placed a quartz apparatus (see FIG. 1). The apparatus was composed of 20 millimeters inner diameter X 25 millimeters outer diameter quartz tubing and a pear-shaped quartz bulb similar in structure to a separatory funnel. There were three main openings, namely, one open horizontal tube end, one vertical 24/40 female ground quartz joint perpendicular to main tube, and one vertical 24/40 male ground quartz joint below the pear-shaped portion. In addition, a 4 millimeter Chem-Cap valve (Chemglass) was located near the open tube end. Quartz wool (about 1 inch plug) was pushed into the apparatus with a rod to a point about 1 inch prior to the onset of curvature of the tube. Five thermocouples (surface mount Omega Type K) were placed on the apparatus at five heating zones. Temperatures were monitored on Thermolyne displays. These zones were then wrapped with heating tape (Barnstead Thermolyne, controlled with Staco variacs) and covered with 0.75 inch ceramic fiber insulation over-wrapped with braided fiberglass. The vaporization zone was centered at the T intersection 6 inches from the left side open end of the apparatus and extended 2 inches to either side of the intersection. The pre-heat zone was centered 13 inches from the open tube end and extended 5 inches to either side. The reaction zone was centered 25 inches from the open tube end and extended 7 inches in either direction.

The reaction zone was also extended around the tube bend. The knock-down zone was the area at the top of the pear-shaped section extending about 2 inches down (the remaining portion of the pear-shaped section was left uncovered). The collection zone was at the collection flask (500 milliliters round bottom in this case, although small or larger flasks may be used depending on scale) and extended up the flask's condensing arm (see FIG. 1). The flask itself could also be heated by a mantle. The flask was placed onto the system with minimal grease (high vacuum Dow Coming silicone grease) or a Teflon sleeve at the ground quartz joint below the pear-shaped section. A Teflon coated stir-bar magnet could also be placed in the flask to facilitate product collection after the run was complete (vide infra). The gas inlet port on the flask (Chem-Cap) was hooked up to the argon supply for purging. To the condensing arm of the flask (which was terminated with a 24/40 female ground glass joint) was attached a ground glass-to-tubing adapter (using minimal grease or a Teflon sleeve) and a Teflon exhaust line.

The exhaust line was led through a 100 milliliter knock-out trap (glass tube) and a glass bubbler (containing Ausimont Galden Perfluorinated Fluid HT 270) before terminating into a 5 liter aqueous NaOH scrubber (5-20% by weight; 1-5 M) vented to the top-back of the fume hood. A standard dry 100 milliliter pressure-equalizing addition funnel with metering valve was placed on the other ground quartz joint at the 4 inch extension near the left-side of the apparatus with minimal grease or a Teflon sleeve, and capped with a septum and stainless steel needle for purging. High purity HfO₂ (50 grams, 0.25 mol, less than 50 parts per million Zr) was loaded into a 14 inch long quartz boat (15 millimeters internal diameter X 18 millimeters outer diameter, quartz tubing closed on either end with the upper 120° of arc ‘removed’ to form top loading boat) and slid into the quartz apparatus using a rod. The open end of the quartz apparatus was fitted with a glass-to-metal reduction fitting attached to a ⅛ inch stainless steel line. A regulated (less than 5 psig) argon supply (Praxair) as well as a regulated (less than 5 psig) chlorine lecture bottle (Praxair sigma-3 grade, 99.998%) were connected to this line, which was also equipped with an isolation valve, rotometer, and a pressure relief valve (5 psig). The argon flow was initiated (200 milliliters/minute).

While the purging was proceeding, anhydrous inert-gas purged CCl₄ (38.5 grams, 24 milliliters, 0.5 mol) was transferred via cannula to the addition funnel. The purge needle was removed once the system had purged (30 minutes). After the argon flow had proceeded for 30 minutes, heating was commenced. Generally temperatures were as follows: vaporization zone 110° C., pre-heat zone 575° C., reaction zone 600° C., and collection zone 150° C. The knock-down zone was only activated periodically during the run to promote release of the product from the pear-shaped section walls to the collection flask. This process was performed roughly every 2 hours by heating up to about 350° C. and then shutting off the heat. After the temperature had stabilized (about 1 hour), the argon flow was terminated and the chlorine flow initiated (100 milliliters/minute). The two gas inlet valves on the quartz system and the collection flask were checked for a tight seal. The chlorine was run for 30 minutes, and then (with the same chlorine flow) the CCl₄ dropwise addition was commenced at a rate of about 4 milliliters/hour. After several seconds white solid was observed in the pear-shaped cool zone and began to slide into the collection flask.

Once the CCl₄ addition was completed (about 6 hours), the chlorine flow was allowed to continue for 30 minutes, after which the chlorine flow was terminated and argon flow was initiated (200 milliliters/minute). After 30 minutes of argon, heating was shut-down and the system was allowed to cool. Once the quartz was cool, any remaining product was tapped down to the collection flask. If a Teflon-coated magnet was placed in the receiver flask earlier, then a second magnet may be used to guide the inner magnet along the walls of the pear-shaped section to enhance product yield. Argon flow was then directed through the collection flask via the gas-inlet side arm and back through the quartz apparatus through the purge gas-inlet valve near the beginning of the system (see FIG. 1); this process allows the flask to be removed without atmospheric contamination). Under this purge, the flask was quickly removed and sealed with an oven dried ground glass stopper. The flask was then brought into an inert atmosphere glove box where the contents could be isolated (note: if grease was used, either carefully remove grease with lint-free clean room cloth and a hydrocarbon solvent or remove material via gas-inlet side arm). Ultra high purity HfCl₄ was analyzed by thermogravimetric analysis (greater than 99%) and inductively coupled plasma mass spectrometry (greater than 99.995%, Zr=7.1 parts per million, Ti=1.3 parts per million). Typically 10% of the HfO₂ is recovered from the system (i.e., remains on the boat) as unreacted material. This material may be reused in subsequent runs without modification. As calculated from the HfO₂ that does react, ultra high purity HfCl₄ is isolated in greater than 90% yield.

### EXAMPLE 2

Within a dry nitrogen atmosphere glove box a dry, three-neck 5 liter round-bottom flask was charged with a stir bar and anhydrous hexanes (2.8 liters). Stirring of the hexanes was commenced, and LiNEt₂ (270.8 grams, 3.42 mol) was added. After stirring for 30 minutes, UHP HfCl₄ (250 grams, 0.78 mol, 7.1 parts per million Zr) was added in portions while stirring rapidly, (about 60% of the total added over about 15 minutes, with the remaining about 40% over about 90 minutes). Anhydrous inhibitor-free THF (Aldrich, 50 milliliters) was added. The white suspension was stirred rapidly for 16 hours, after which the white solids were allowed to settle (1 hour) yielding a clear yellow supernatant.

The entire contents of the flask were filtered through a 2 liter fine frit. The remaining white solids were rinsed with hexanes. The solvent was removed from the crude product under reduced pressure, yielding about 400 milliliters of yellow/orange liquid with white residue.

The above procedure was repeated, thus yielding a total of about 800 milliliters of yellow/orange crude product.

The crude product was vacuum distilled utilizing air-free glassware and a Schlenk line. Although one distillation yields greater than 99% purity, a second distillation was performed using similar techniques to ensure optimum purity. A lights cut (about 5 milliliters) was taken each time, and a heel (about 10 milliliters) was left after the final distillation. During the distillation, the following values were observed: 130° C. at the pot, 90° C. at the head, and 0.05 torr on the line. After the two distillations, the isolated ultra high purity tetrakis(diethylamino)hafnium (UHP TDEAH) (619 grams, 1.33 mol, 85%) was a practically colorless, clear liquid. Upon repeated preparations for this material, isolated yields were typically 85%±5%. ¹H NMR (>99% pure), 300 MHz, C₆D₆, (3.37, q, J=7, CH₂, 16H; 1.16, t, J=7, CH₃, 24H), TGA (0.1% NVR), ICP-MS (>99.999% Hf, 3.6 parts per million Zr, <1 part per million other metals).

This invention is distinguished from the prior art in several ways. For example, high purity HfO₂ is utilized in the process of this invention, e.g., HfO₂ with at least less than 0.01% and as low as less than 0.001% Zr and Ti impurities. This specification is far more stringent than Oak Ridge's reported process supra, which utilized HfO₂ with 1% Zr and 0.2% Ti. This change can effect yield, consistency, mesh size, and (most importantly) will result in a purer product. Also, quartz tubing is utilized in the process of this invention. By using quartz tubing (compared to Pyrex as used by Oak Ridge), higher temperatures may be utilized if desired. Quartz can be operated at greater than 500° C. hotter than Pyrex. This flexibility can allow for greater efficiency, throughput, and yield. Furthermore, Pyrex contains dopants such as boron which at higher temperatures can leach into the reacting reagents causing the presence of impurities in the final product. This potential for contamination is cause for concern especially for semiconductor applications. The use of a metal apparatus, although allowing for high temperatures like quartz, has the drawback of potential metal contamination and corrosion. The shape of the quartz apparatus is a novel approach as well.

It was discovered that a straight tube design did not allow for high throughput as clogging could occur. With the pear-shape design, the gaseous product is allowed to expand and cool more rapidly and condense in a wider area, therefore maximizing yield and efficiency. Further, this process is air/moisture free. For the Oak Ridge reported process supra (and most known industrial scale processes), the final product is, at a minimum, briefly exposed to air while the product is recovered from the reactor. This exposure inevitably leads to some impurity formation in the form of HCl and HfO₂. The process of this invention is set up in such a way as to allow for the product to be recovered without air or moisture exposure at any time, thus generating a purer product.

Two additional key observations for this invention include the option of not using chlorine gas and the elimination of an impurity, namely hexachloroethane. It was discovered that using CCl₄ in the presence of an argon flow (as opposed to chlorine) also yielded substantial amounts of product. Although more CCl₄ was necessary for this process and efficiency was not as high, with further optimization it may prove a promising alternative to dealing with a toxic gas such as chlorine. Secondly, the hexachloroethane impurity was identified in the process by gas chromatographic measurements. Not indicated by earlier literature methods for lower purity material, this compound results from the combination of CCl₃ radicals. The presence of this molecule could interfere with performance for electronic applications. The example above generates HfCl₄ with undetectable levels (gas chromatography) of hexachloroethane. Although the system can be run faster if necessary, levels of hexachloroethane typically increase. If that occurs, the HfCl₄ can be purified to ultra high purity levels by sublimation off the impurity away from the desired product (hexachloroethane sublimes about 190° C.).

Also, other carbon and chlorine sources can be used in the process of this invention. Other sources of carbon and chlorine may be utilized to benefit yield, adjust reaction conditions (temperature, reaction time, efficiency), and/or limit production of hazardous byproducts (e.g., phosgene). Examples include: C (e.g., activated graphite/charcoal), CO, CO₂, hydrocarbons, Cl₂, CCl₄, HCCl₃, H₂CCl₂, H₃CCl, and the like.

1. A composition comprising a hafnium-containing compound represented by the formula Hf(R)ₘ wherein R is the same or different and represents a halogen atom, a pseudohalogen group, an acyl group having from 1 to about 12 carbon atoms, an alkoxy group having from 1 to about 12 carbon atoms, an alkoxycarbonyl group having from 1 to about 12 carbon atoms, an alkyl group having from 1 to about 12 carbon atoms, an amino group having from 1 to about 12 carbon atoms, an imino group having from 1 to about 12 carbon atoms, a silyl group having from 0 to about 12 carbon atoms, an allyl-like group having from 1 to about 12 carbon atoms, a beta-diketonato group having from 1 to about 12 carbon atoms, or an amidinato group having from 1 to about 12 carbon atoms, m is a value of from 1 to 4, and wherein said composition has a zirconium concentration of less than about 500 parts per million.

2. An organometallic precursor composition comprising a hafnium-containing compound represented by the formula Hf(R)ₘ wherein R is the same or different and represents a halogen atom, a pseudohalogen group, an acyl group having from 1 to about 12 carbon atoms, an alkoxy group having from 1 to about 12 carbon atoms, an alkoxycarbonyl group having from 1 to about 12 carbon atoms, an alkyl group having from 1 to about 12 carbon atoms, an amino group having from 1 to about 12 carbon atoms, an imino group having from 1 to about 12 carbon atoms, a silyl group having from 0 to about 12 carbon atoms, an allyl-like group having from 1 to about 12 carbon atoms, a beta-diketonato group having from 1 to about 12 carbon atoms, or an amidinato group having from 1 to about 12 carbon atoms, m is a value of from 1 to 4, and wherein said composition has a zirconium concentration of less than about 500 parts per million.

3. The composition of claim 1 having a zirconium concentration of less than about 250 parts per million.

4. The composition of claim 1 having a zirconium concentration of less than about 100 parts per million.

5. The composition of claim 1 having a zirconium concentration of less than about 10 parts per million.

6. The composition of claim 1 having a zirconium concentration of less than about 5 parts per million.

7. The composition of claim 1 wherein said hafnium-containing compound is selected from tetrakis(dimethylamino)hafnium (TDMAH), tetrakis(ethylmethylamino)hafnium (TEMAH), tetrakis(diethylamino)hafnium (TDEAH), hafnium amide, hafnium (IV) tert-butoxide, hafnium (IV) acetylacetonate, bis(ethylcyclopentadienyl)dimethylhafnium or t-butylimidobis(dimethylamino)hafnium.

8. A process for producing a composition comprising a hafnium-containing compound represented by the formula Hf(R)ₘ wherein R is the same or different and represents a halogen atom, a pseudohalogen group, an acyl group having from 1 to about 12 carbon atoms, an alkoxy group having from 1 to about 12 carbon atoms, an alkoxycarbonyl group having from 1 to about 12 carbon atoms, an alkyl group having from 1 to about 12 carbon atoms, an amino group having from 1 to about 12 carbon atoms, an imino group having from 1 to about 12 carbon atoms, a silyl group having from 0 to about 12 carbon atoms, an allyl-like group having from 1 to about 12 carbon atoms, a beta-diketonato group having from 1 to about 12 carbon atoms, or an amidinato group having from 1 to about 12 carbon atoms, m is a value of from 1 to 4, and wherein said composition has a zirconium concentration of less than about 500 parts per million, which process comprises reacting a hydrocarbon or heteroatom-containing compound with a hafnium halide compound represented by the formula Hf(X)₄ wherein X is the same or different and is a halide and wherein said hafnium halide compound has a zirconium concentration of less than about 500 parts per million, under reaction conditions sufficient to produce said composition.

9. The process of claim 8 wherein said hydrocarbon or heteroatom-containing compound is selected from a lithiated amide, alkoxide, diketonate, cyclopentadienide or imide.

10. The process of claim 8 wherein said hafnium halide compound is selected from HfCl₄, HfF₄, HfBr₄, or HfI₄.

11. The process of claim 8 wherein said hafnium-containing compound is selected from tetrakis(dimethylamino)hafnium (TDMAH), tetrakis(ethylmethylamino)hafnium (TEMAH), tetrakis(diethylamino)hafnium (TDEAH), hafnium amide, hafnium (IV) tert-butoxide, hafnium (IV) acetylacetonate, bis(ethylcyclopentadienyl)dimethylhafnium or t-butylimidobis(dimethylamino)hafnium.

12. A method for producing a hafnium-containing film, coating or powder having a zirconium concentration of less than about 500 parts per million, which method comprises decomposing an organometallic precursor composition comprising a hafnium-containing compound, thereby producing the film, coating or powder, wherein said hafnium-containing compound is represented by the formula Hf(R)ₘ wherein R is the same or different and represents a halogen atom, a pseudohalogen group, an acyl group having from 1 to about 12 carbon atoms, an alkoxy group having from 1 to about 12 carbon atoms, an alkoxycarbonyl group having from 1 to about 12 carbon atoms, an alkyl group having from 1 to about 12 carbon atoms, an amino group having from 1 to about 12 carbon atoms, an imino group having from 1 to about 12 carbon atoms, a silyl group having from 0 to about 12 carbon atoms, an allyl-like group having from 1 to about 12 carbon atoms, a beta-diketonato group having from 1 to about 12 carbon atoms, or an amidinato group having from 1 to about 12 carbon atoms, m is a value of from 1 to 4, and wherein said organometallic precursor composition has a zirconium concentration of less than about 500 parts per million.

13. The method of claim 12 wherein the decomposing of said organometallic precursor composition comprising a hafnium-containing compound is thermal, chemical, photochemical or plasma-activated.

14. The method of claim 12 wherein said organometallic precursor composition comprising a hafnium-containing compound is vaporized and the vapor is directed into a deposition reactor housing a substrate.

15. The method of claim 14 wherein said substrate is comprised of a material selected from the group consisting of a metal, a metal silicide, a semiconductor, an insulator and a barrier material.

16. The method of claim 15 wherein said substrate is a patterned wafer.

17. The method of claim 12 wherein said film, coating or powder is produced by a gas phase deposition.

18. The method of claim 12 wherein said organometallic precursor composition comprising a hafnium-containing compound is selected from tetrakis(dimethylamino)hafnium (TDMAH), tetrakis(ethylmethylamino)hafnium (TEMAH), tetrakis(diethylamino)hafnium (TDEAH), hafnium amide, hafnium (IV) tert-butoxide, hafnium (IV) acetylacetonate, bis(ethylcyclopentadienyl)dimethylhafnium or t-butylimidobis(dimethylamino)hafnium.

19. A mixture comprising (i) a composition comprising a hafnium-containing compound represented by the formula Hf(R)ₘ wherein R is the same or different and represents a halogen atom, a pseudohalogen group, an acyl group having from 1 to about 12 carbon atoms, an alkoxy group having from 1 to about 12 carbon atoms, an alkoxycarbonyl group having from 1 to about 12 carbon atoms, an alkyl group having from 1 to about 12 carbon atoms, an amino group having from 1 to about 12 carbon atoms, an imino group having from 1 to about 12 carbon atoms, a silyl group having from 0 to about 12 carbon atoms, an allyl-like group having from 1 to about 12 carbon atoms, a beta-diketonato group having from 1 to about 12 carbon atoms, or an amidinato group having from 1 to about 12 carbon atoms, m is a value of from 1 to 4, and wherein said composition has a zirconium concentration of less than about 500 parts per million, and (ii) one or more different organometallic compounds.

20. The mixture of claim 19 wherein said one or more other organometallic compounds are selected from a ruthenium-containing, tantalum-containing or molybdenum-containing organometallic compound.
